(19) United States
(12) Patent Application Publication
(10) Pub. No.: US 2016/0079405 A1
(43) Pub. Date: Mar. 17, 2016

(54) SEMICONDUCTOR DEVICE

(71) Applicant: KABUSHIKI KAISHA TOSHIBA, Tokyo (JP)

(72) Inventor: Kazuo SAKI, Kanazawa Ishikawa (JP)

(21) Appl. No.: 14/626,639

(22) Filed: Feb. 19, 2015

(30) Foreign Application Priority Data
Sep. 12, 2014 (JP) 2014-186161

(51) Int. Cl. H01L 29/778; H01L 29/417; H01L 21/02; H01L 29/66; H01L 29/20

(52) U.S. Cl. CPC H01L 29/7787; H01L 29/66462; H01L 29/2003; H01L 21/02274; H01L 29/41758; H01L 29/41775; H01L 21/0217

(57) ABSTRACT

According to an embodiment, a semiconductor device includes a first semiconductor layer, a second semiconductor layer, a first electrode, and a first insulating film. The first semiconductor layer includes a nitride semiconductor. The second semiconductor layer is provided over the first semiconductor layer, includes a nitride semiconductor, and contains composition different from the composition of the first semiconductor layer. The first insulating film is provided over the second semiconductor layer, covers at least a part of the first electrode, and contains silicon nitride. The hydrogen concentration in the first insulating film is greater than or equal to 5.0×10²¹ atoms/cm³ and less than or equal to 9.0×10²¹ atoms/cm³.

### CROSS-REFERENCE TO RELATED APPLICATION

This application is based upon and claims the benefit of priority from Japanese Patent Application No. 2014-186161, filed Sep. 12, 2014; the entire contents of which are incorporated herein by reference.

### FIELD

Embodiments described herein relate generally to a semiconductor device.

### BACKGROUND

Polarization occurs in a nitride semiconductor when nitride semiconductors of different lattice constants are disposed in contact with each other, and free electrons are generated therein adjacent the interface of the nitride layers having different lattice constants. These free electrons are distributed two-dimensionally in the vicinity of the interface between the nitride semiconductors and are known as a two-dimensional electron gas. The electrons in the two-dimensional electron gas have high mobility. Therefore, a semiconductor device such as a high electron mobility transistor (HEMT) that uses the two-dimensional electron gas region as a channel may operate at a high speed. Characteristics of a transistor such as an ON resistance and an ON current depend on the density of carriers in the channel. Therefore, characteristics of a semiconductor device may vary when the density of the two-dimensional electron gas varies.

### DESCRIPTION OF THE DRAWINGS

FIG. 1 is a cross-sectional diagram schematically illustrating a semiconductor device according to an embodiment.

FIG. 2 is a graph illustrating a characteristic of silicon nitride.

FIG. 3 is a graph illustrating a relationship between variations in characteristics of the semiconductor device and stress on an interlayer insulating film.

FIGS. 4A to 4D are cross-sectional diagrams schematically illustrating a method for manufacturing the semiconductor device according to the embodiment.

### DETAILED DESCRIPTION

An embodiment provides a semiconductor device that may control variations in characteristics thereof.

In general, according to one embodiment, a semiconductor device includes a first semiconductor layer, a second semiconductor layer, a first electrode, and a first insulating film. The first semiconductor layer includes a nitride semiconductor. The second semiconductor layer is provided over the first semiconductor layer, includes a nitride semiconductor, and contains a composition different from the composition of the first semiconductor layer. The first insulating film is provided over the second semiconductor layer, covers at least a part of the first electrode, and contains silicon nitride. The hydrogen concentration in the first insulating film is greater than or equal to 5.0×10²¹ atoms/cm³ and less than or equal to 9.0×10²¹ atoms/cm³.

Hereinafter, each embodiment will be described with reference to the drawings.

The drawings are illustrated in a schematic or conceptual manner. Thus, the relationship between the thickness and the width of each part, the proportions in size of each part, and the like are not necessarily the same as those of an actual device. In addition, an element, film layer, and the like may be represented differently in dimension or proportion depending on each of the drawings even in a case of the same element, film layer, etc.

The same elements as those described previously in the drawings are given the same reference numerals or symbols, and detailed descriptions thereof will be appropriately omitted in the present disclosure.

The terms “over” and “under” are used in the present disclosure for convenience of description. The expression “disposed over” includes not only a case where “one that is disposed over another” is in direct contact with “the other that is disposed under the one” but also a case where another element is interposed between the two elements.

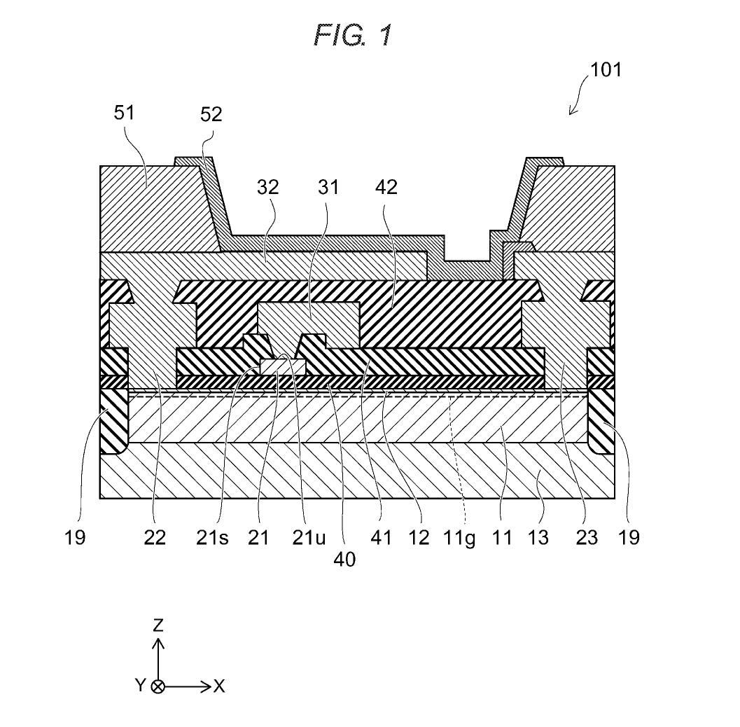

FIG. 1 is a cross-sectional diagram schematically illustrating a semiconductor device 101 according to an embodiment.

The semiconductor device 101, for example, is an HEMT made from a nitride semiconductor.

The semiconductor device 101 is provided with a first semiconductor layer 11, a second semiconductor layer 12, and a third semiconductor layer 13. The semiconductor device 101 is further provided with a gate electrode 21 (first electrode), a source electrode 22 (second electrode), a drain electrode 23 (third electrode), a gate insulating film. 40, an interlayer insulating film 41 (first insulating film), an insulating film 42, field plate electrodes 31 and 32, a pad portion 51, and a protective film 52.

In FIG. 1, the direction extending from the first semiconductor layer 11 to the second semiconductor layer 12 is a Z axis direction. One of directions that are perpendicular to the Z axis direction is an X axis direction. The direction that is perpendicular to the Z axis direction and the X axis direction is a Y axis direction.

The third semiconductor layer 13 is a layer that serves as a base for growing a nitride semiconductor crystal. Gallium nitride (GaN) having high resistance or semi-insulating characteristics is used as the material of the third semiconductor layer 13.

The first semiconductor layer 11 is disposed over the third semiconductor layer 13. The first semiconductor layer 11 is a channel layer and includes Alₓ₁Ga₁₋ₓ₁N (where 0≦x1<1).

The second semiconductor layer 12 is disposed over the first semiconductor layer 11. The second semiconductor layer 12 is a barrier layer and includes Alₓ₂Ga₁₋ₓ₂N (where x1<x2<1). The second semiconductor layer 12 forms a heterojunction with the first semiconductor layer 11.

The source electrode 22 and the drain electrode 23 are each disposed over the second semiconductor layer 12 and are electrically connected to the second semiconductor layer 12. The source electrode 22 is spaced from the drain electrode 23 in the X axis direction.

Materials such as aluminum (Al), titanium (Ti), nickel (Ni), gold (Au), tungsten (W), molybdenum (Mo), tantalum (Ta), and titanium nitride (TiN) or combinations thereof may be used as the material of the source electrode 22 and the drain electrode 23.

An insulating region 19 extends through the first and second semiconductor layers 11, 12, and inwardly of the third semiconductor layer 13. The insulating region creates electrically insulated device regions within the circumference thereof. The insulating area 19 is disposed to surround the region of the source electrode 22 and the drain electrode 23. The insulating area 19 is disposed at a depth to extend inwardly of the third semiconductor layer 13.

A gate insulating film 40 is disposed between the second semiconductor layer 12 and the gate electrode 21. The gate insulating film 40 is disposed when necessary and may be omitted. Materials such as SiO₂, SiN, Al₂O₃, TiO₂, Ta₂O₅, HfO₂, or ZrO₂ may be used as the material of the gate insulating film 40. The gate electrode 21 is disposed between the source electrode 22 and the drain electrode 23. Materials such as aluminum (Al), titanium (Ti), nickel (Ni), gold (Au), and titanium nitride (TiN) may be used as the material of the gate electrode 21. The gate electrode is disposed on the gate insulating film 40, when present.

An interlayer insulating film 41 extends between the gate electrode 21 and the source electrode 22 and between the gate electrode 21 and the drain electrode 23, and over the second semiconductor layer 12 (and gate insulating layer 40 where present). The interlayer insulating film 41 covers a part of an upper surface 21u of the gate electrode 21. The interlayer insulating film 41 further covers a side surface 21s (a surface intersecting the X axis direction or the Y axis direction) of the gate electrode 21.

Silicon nitride (SiN) is used as the material of the interlayer insulating film 41. The thickness of the interlayer insulating film 41 is, for example, 200 nm.

The hydrogen concentration in the interlayer insulating film 41 has a distinctive range in the present embodiment. For example, the hydrogen concentration in the interlayer insulating film 41 is greater than or equal to 5.0×10³¹ atoms/cm³ and smaller than or equal to 9.0×10²¹ atoms/cm³.

A first field plate electrode 31 (FP electrode 31 hereinafter) has a part thereof disposed over the gate electrode 21 and a part thereof extending from over the gate electrode 21 to the drain electrode 23. The first FP electrode 31 is electrically connected to the gate electrode 21. The first FP electrode 31 is a part of gate wiring that supplies a gate bias to the gate electrode 21. The first FP electrode 31 simultaneously functions as a field plate. Aluminum (Al) and/or titanium (Ti) may be used as the material of the first FP electrode 31.

An insulating film 42 is disposed over the interlayer insulating film 41. The insulating film 42 has a portion thereof disposed between the source electrode 22 and the first FP electrode 31, a portion thereof disposed between the drain electrode 23 and the first FP electrode 31, and a portion thereof disposed over the first FP electrode 31. Silicon oxide (SiO₂) or silicon nitride may be used as the material of the insulating film 42.

An additional second field plate electrode 32 (FP electrode 32 hereinafter) is disposed over the insulating film 42. The second FP electrode 32 has a portion thereof disposed over the first FP electrode 31 and a portion thereof extending from a location over the first FP electrode 31 to a location between the first field plate electrode and the drain electrode 23. The second FP electrode 32 is electrically connected to the source electrode 22. Materials such as aluminum (Al) and/or titanium (Ti) may be used as the material of the second FP electrode 32.

A pad portion 51 is disposed over the source electrode and the drain electrode 23. The pad portion 51 is electrically connected to the source electrode 22 or the drain electrode 23. A protective film 52 covers areas such as an upper part of the second FP electrode 32 and a side surface of the pad portion 51.

The lattice constant of the first semiconductor layer 11 (Alₓ₁Ga₁₋ₓ₁N) differs from the lattice constant of the second semiconductor layer 12 (Alₓ₂Ga₁₋ₓ₂N). When nitride semiconductor layers having different lattice constants form a heterojunction with each other, the difference between lattice constants causes distortions on the interface therebetween, and stress is applied to the first semiconductor layer 11. The stress allows a piezoelectric effect to occur, and a two-dimensional electron gas 11g region is formed at the interface of the first and second semiconductor layers 11, 12. The two-dimensional electron gas 11g region forms a channel region of a transistor of the device.

The free electron, or carrier, density in the two-dimensional electron gas 11g region under the gate electrode 21 is increased or decreased by controlling a voltage applied to the gate electrode 21 in the semiconductor device 101. Accordingly, a current flowing between the source electrode 22 and the drain electrode 23 may be controlled. The semiconductor device 101 may be a normally-on or a normally-off semiconductor device.

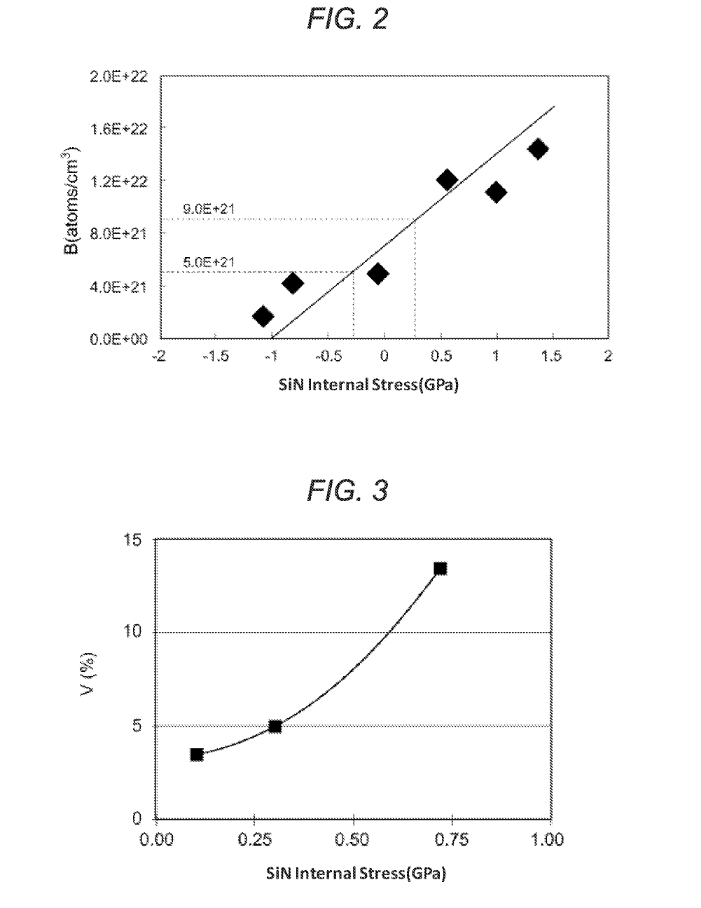

FIG. 2 is a graph illustrating a characteristic of silicon nitride.

FIG. 2 represents a hydrogen concentration B (atoms/cm³) in a SiN film stacked on a Si wafer. The hydrogen concentration is measured by using Fourier transform infrared spectroscopy (FT-IR). The hydrogen concentration is calculated by analyzing the density of Si—H bonds and N—H bonds. The hydrogen concentration may be measured by using secondary ion mass spectrometry (SIMS). The same result as the hydrogen concentration illustrated in FIG. 2 may be obtained by the measurement using SIMS.

The horizontal axis in FIG. 2 represents an internal stress of the SiN film. Curvature caused in the wafer by the stacking of the SiN film is measured, and the internal stress of the SiN film is obtained from the measured amount of curvature. Positive values on the horizontal axis in FIG. 2 represent tensile stress, and negative values represent compressive stress.

The internal stress of the SiN film depends on the hydrogen concentration in the SiN film as illustrated in FIG. 2.

When the absolute value of the stress in the SiN film is smaller than or equal to 0.3 GPa, the hydrogen concentration in the SiN film is greater than or equal to 4.5×10²¹ atoms/cm³ and less than or equal to 9.50×10²¹ atoms/cm³. When the absolute value of the stress on the SiN film is less than or equal to 0.25 GPa, the hydrogen concentration in the SiN film is greater than or equal to 5.0×10²¹ atoms/cm³ and less than or equal to 9.0×10²¹ atoms/cm³. Although FIG. 2 illustrates the relationship related to the SiN film on the Si wafer, it is considered that the same relationship is established for the interlayer insulating film 41 that includes SiN.

The hydrogen concentration in the interlayer insulating film 41 of the semiconductor device 101 is greater than or equal to 5.0×10²¹ atoms/cm³ and smaller than or equal to 9.0×10²¹ atoms/cm³.

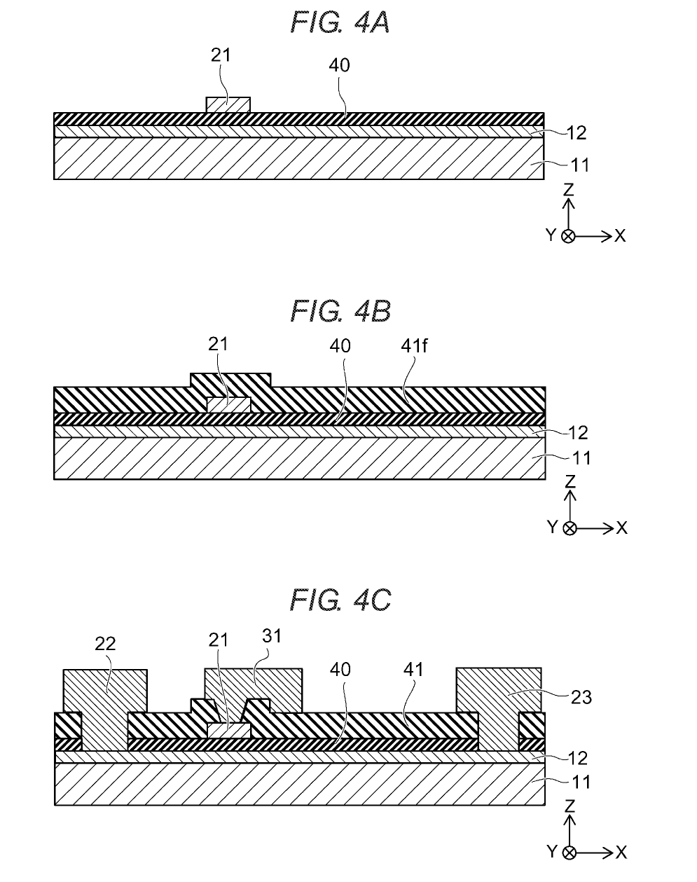

FIG. 3 is a graph illustrating the relationship between variations in characteristics of the semiconductor device and the internal stress in the SiN film used in the interlayer insulating film 41. That is to say, FIG. 3 represents a result of measuring characteristics of the HEMT in which conditions for forming the SiN film (interlayer insulating film 41) are different from each other.

The horizontal axis in FIG. 3 represents the absolute value of the internal stress (in GPa) on the SiN film. The internal stress may be obtained from the amount of curvature of the Si wafer on which the SiN film is stacked in the same conditions as the conditions for forming the interlayer insulating film 41.

The vertical axis in FIG. 3 represents a variation V (in percentages (%)) of the ON resistance in the HEMT.

The variation V (in %) is calculated in the following manner. First, the ON resistance of the HEMT is measured at multiple places in the surface of the wafer in each of the conditions of forming the interlayer insulating film 41. In each of the forming conditions, the standard deviation (a) and the average value (Av) of the multiple ON resistance values are calculated, and the variation V (in %) is calculated as a ratio of 3σ (in %) to the average value Av. Variation values in conditions where the absolute values of the internal stress on the SiN film are 0.1 GPa, 0.3 GPa, and 0.7 GPa are illustrated in FIG. 3.

Variations in the ON resistance of the semiconductor device increase when the absolute value of the internal stress on the SiN film increases as represented in FIG. 3. When the absolute value of the internal stress on the SiN film is greater than or equal to 0.3 GPa, the variation V is greater than or equal to 5%.

In addition, the variation V rapidly increases as the absolute value of the internal stress in the SiN film increases above 0.3 GPa. That is to say, above an internal stress of 0.3 GPa, a change in the variation V is large in comparison to an increase in the internal stress above 0.3 GPa. In this manner, when the absolute value of the internal stress on the SiN film exceeds 0.3 GPa, the two-dimensional electron gas region is greatly influenced, and variations in the ON resistance become great.

The internal stress in the interlayer insulating film 41 causes stress on the first semiconductor layer 11 through the gate insulating film 40 and the second semiconductor layer 12. That is to say, distortions caused at the interface between the first semiconductor layer 11 and the second semiconductor layer 12 are influenced by not only the stress caused due to the difference between the lattice constant of the first semiconductor layer 11 and the second semiconductor layer 12 but also the internal stress in the interlayer insulating film 41.

The stress imposed on the first semiconductor layer 11 by the interlayer insulating film 41 influences a piezoelectric electric field generated at the interface of the first semiconductor layer 11 and second semiconductor layer 12. This causes the carrier density in the two-dimensional electron gas region to vary.

Characteristics of a transistor such as the ON resistance, the ON current, and the switching operation depend on (the carrier density of) the two-dimensional electron gas region. Therefore, when the stress caused at the interface by the interlayer insulating film 41 varies, characteristics of the semiconductor device may vary.

The internal stress in the interlayer insulating film 41 varies when, for example, conditions for depositing the interlayer insulating film 41 vary in the manufacturing process for the semiconductor device. Accordingly, stress caused on the interface between an AlGaN layer and a GaN layer varies, and characteristics of the semiconductor device vary.

As represented in FIG. 1, electrodes, wiring, and the like are partly formed in the layer where the interlayer insulating film 41 is formed. For example, the interlayer insulating film 41 is formed between the gate electrode 21 and the source electrode 22 and between the gate electrode 21 and the drain electrode 23. Therefore, distortions are not uniform on the interface between the first semiconductor layer 11 and the second semiconductor layer 12. For example, the magnitude of distortion under the interlayer insulating film 41 differs from the magnitude of distortion under the source electrode 22. Therefore, when the dimensions of the electrodes vary, and the dimensions of the interlayer insulating film 41 vary in manufacturing of the semiconductor device, the carrier density in the two-dimensional electron gas region varies.

In addition, the dimensions and conditions for forming the interlayer insulating film 41 are not the same across the surface of the wafer due to variations in manufacturing. Therefore, the stress exerted on the interface between the AlGaN layer and the GaN layer by the interlayer insulating film 41 may not be the same across the surface of the wafer. There may be a difference between characteristics of a semiconductor device disposed at the center of the wafer and characteristics of a semiconductor device disposed adjacent the outer circumference of the wafer.

When the absolute value of the internal stress on the interlayer insulating film 41 is large, the interlayer insulating film 41 greatly influences the distortions, and the carrier density of the two-dimensional electron gas is greatly influenced. Therefore, the carrier density of electrons is likely to vary, and characteristics of the semiconductor device are likely to vary due to variations in the internal stress on the interlayer insulating film 41.

Regarding this point, the absolute value of the internal stress on the interlayer insulating film 41 is decreased in the semiconductor device 101 according to the embodiment. When the internal stress in the interlayer insulating film 41 is small, the internal stress in the interlayer insulating film 41 only slightly influences the stress on the interface of the first semiconductor layer 11. That is to say, the internal stress on the interlayer insulating film 41 only slightly influences the two-dimensional electron gas region when it is small. Therefore, decreasing the internal stress in the interlayer insulating film 41 may reduce variations of the two-dimensional electron gas region even when the internal stress in the interlayer insulating film 41 varies.

The internal stress in the interlayer insulating film 41 depends on the hydrogen concentration in the interlayer insulating film 41 as described above. Controlling the hydrogen concentration in the interlayer insulating film 41 may decrease the internal stress in the interlayer insulating film 41. In the embodiment, the hydrogen concentration is greater than or equal to 5.0×10²¹ atoms/cm³ and smaller than or equal to 9.0×10²¹ atoms/cm³. This may decrease the absolute value of the internal stress in the interlayer insulating film 41. Decreasing the internal stress in the interlayer insulating film 41 may reduce the influence of the interlayer insulating film 41 on the carrier density in the electron gas region. This may control variations in the carrier density. Therefore, variations in characteristics such as the ON resistance due to variations in the carrier density may be controlled by controlling the hydrogen concentration in the interlayer insulating film 41.

The interlayer insulating film 41 is positioned, for example, between the gate electrode 21 and the source electrode 22. Therefore, even in the semiconductor device 101 according to the embodiment, the dimensions of the interlayer insulating film 41 vary due to variations in the dimensions of the electrodes. However, in the embodiment, the internal stress in the interlayer insulating film 41 is small, and the interlayer insulating film. 41 slightly influences the carrier density in the electron gas region. Therefore, even when the dimensions of the interlayer insulating film 41 vary, the interlayer insulating film. 41 slightly influences the carrier density in the electron gas region.

The thickness of the interlayer insulating film 41 is greater than or equal to 100 nm and smaller than or equal to 300 nm in the present embodiment. The interlayer insulating film 41, for example, desirably has a sufficient thickness in view of securing insulating characteristics and breakdown voltage. The stress in the interlayer insulating film 41 may increase as the interlayer insulating film 41 is thickened. However, the internal stress on the interlayer insulating film 41 may be decreased by controlling the hydrogen concentration in the interlayer insulating film 41 in the embodiment. Accordingly, the internal stress in the interlayer insulating film 41 may be decreased even for an interlayer insulating film 41 having a sufficient thickness, and this may reduce the influence of the interlayer insulating film 41 on the carrier density in the electron gas region.

Revising the disposition or the dimensions of the electrodes lined up with the interlayer insulating film 41 has also been considered as a way to suppress variations in the carrier density of the two-dimensional electron gas region in a case where, for example, the dimensions of the electrodes or the wiring vary. However, the flexibility decreases in designing the electrodes or the wiring, and characteristics of the semiconductor device deteriorates in this case. When, for example, the width of the source electrode 22 or the first FP electrode 31 is decreased, the area where the interlayer insulating film 41 is relatively uniformly disposed may be widened, and this may reduce the influence of variations in the dimensions of the electrodes. However, the contact resistance between the source electrode 22 and the second semiconductor layer 12 will increase when the width of the source electrode 22 is decreased. In addition, the breakdown voltage of the FP electrode 31 decreases when the width of the first FP electrode 31 is decreased.

Regarding this point, reducing the influence of the internal stress on the interlayer insulating film 41 on the carrier density may reduce variations in the carrier density when the dimensions of the electrodes vary. Since variations in the carrier density do not depend on the design for the electrodes or the wiring, flexibility may be secured in designing the electrodes or the wiring.

Next, a method for manufacturing the semiconductor device 101 will be described.

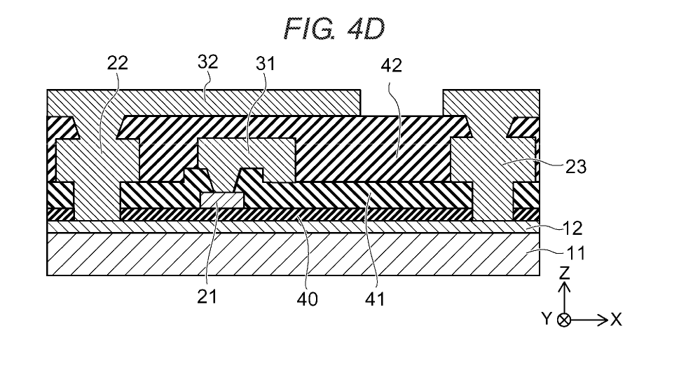

FIGS. 4A to 4D are cross-sectional diagrams schematically illustrating a method for manufacturing the semiconductor device 101 according to the embodiment.

The gate insulating film 40 is formed over the wafer in which the first semiconductor layer 11 and the second semiconductor layer 12 are formed as illustrated in FIG. 4A.

Low pressure chemical vapor deposition (LP-CVD) is used to form a SiN film used as the gate insulating film 40. The thickness of the gate insulating film is greater than or equal to 10 nm and smaller than or equal to 30 nm, and is 20 nm in this example.

A TiN film serving as the gate electrode 21 is thereafter formed over the gate insulating film 40. The TiN film is processed into the gate electrode 21 using lithography and etching techniques. Physical vapor deposition (PVD) may be used to form the TiN film. Reactive ion etching (RIE) may be used to etch the TiN film through a patterned mask to form the gate electrode 21.

The width (the length along the X axis direction) of the gate electrode 21 is greater than or equal to 1.0 micrometer (μm) and smaller than or equal to 3.0 μm.

An SiN film 41f serving as the interlayer insulating film 41 is formed thereafter as illustrated in FIG. 4B. The SiN film 41f covers the gate electrode 21 and the gate insulating film 40. Plasma CVD may be used to form the SiN film 41f. A SiH₄ gas, an NH₃ gas, and an N₂ gas are used in forming SiN by plasma chemical vapor deposition (CVD).

When the SiN film 41f is formed, the hydrogen concentration in the SiN film may be adjusted by appropriately adjusting conditions such as the temperature of the wafer, the pressure inside a chamber, the flow rate of each gas, and the power (RF power) of a device.

As an example, the temperature of the wafer is set to 375° C., the pressure inside the chamber to 320 Pa, the RF power to 50 W, the flow rate of the SiH₄ gas to 20 sccm (standard cc/min), and the flow rate of the NH₃ gas to 60 sccm. This may adjust the hydrogen concentration in the interlayer insulating film 41 to approximately 7.0×10²¹ atoms/cm³.

The thickness of the interlayer insulating film 41 is, for example, greater than or equal to 100 nm and smaller than or equal to 300 nm, and is 200 nm in this example.

Openings are disposed in the SiN film 41f thereafter according to the positions where the source electrode 22 and the drain electrode 23 are to be located, and metal films (for example, a Ti film and an Al film) are formed by sputtering (PVD) as illustrated in FIG. 4C. The metal films are processed by lithography and etching steps, to form the source electrode 22 and the drain electrode 23. The first FP electrode 31 is also formed in the same manner.

The width of the source electrode 22 is, for example, greater than or equal to 3 μm and smaller than or equal to 8 μm.

The distance between the source electrode 22 and the gate electrode 21 is, for example, greater than or equal to 1 μm and smaller than or equal to 3 μm.

The distance between the gate electrode 21 and the drain electrode 23 is, for example, greater than or equal to 5 μm and smaller than or equal to 20 μm.

A SiO₂ film serving as the insulating film 42 is formed thereafter, as illustrated in FIG. 4D. The SiO₂ film covers the first FP electrode 31, the source electrode 22, the drain electrode 23, and the interlayer insulating film 41. The SiO₂ film is then processed to form openings for the second FP electrode 32 and pad 51.

The pad portion 51 and the protective film 52 are further formed thereafter, and the semiconductor device 101 is completed.

The semiconductor device is manufactured by controlling the concentration of hydrogen included in the interlayer insulating film 41 as described hereinbefore. Controlling the hydrogen concentration in the interlayer insulating film 41 may decrease the internal stress of the interlayer insulating film 41. Specifically, the hydrogen concentration in the interlayer insulating film 41 is set to be greater than or equal to 5.0×10²¹ atoms/cm³ and smaller than or equal to 9.0×10²¹ atoms/cm³. Accordingly, the internal stress of the interlayer insulating film 41 may have a reduced influence on the stress on the interface of the nitride semiconductor. The two-dimensional electron gas region is generated by the stress on the interface of the nitride semiconductor layers. Therefore, decreasing the absolute value of the internal stress of the interlayer insulating film 41 may reduce the influence of the internal stress of the interlayer insulating film 41 on the two-dimensional electron gas region. This may suppress variations in the carrier density of the two-dimensional electron gas region even when the internal stress of the interlayer insulating film 41 varies. Therefore, variations in resulting device characteristics such as the ON resistance and the ON current may be suppressed in an HEMT that uses the two-dimensional electron gas region as the channel.

In the present disclosure, the term “nitride semiconductor” includes Group III-V compound semiconductors of BₓIn_{y}Al_{z}Ga_{1-x-y-z}N (where 0≦x≦1, 0≦y≦1, 0≦z≦1, and 0≦x+y+z≦1) and further includes a mixed crystal containing phosphorus (P), arsenic (As), or the like as a Group V element in addition to nitrogen (N). Furthermore, the term “nitride semiconductor” includes a mixed crystal further including various elements added for controlling various properties of materials such as conductivity and includes a mixed crystal further including various elements that are unintentionally included therein.

The first to the third semiconductor layers 11 to 13 are not limited to a nitride semiconductor. Other semiconductors such as SiC, GaAs, InP, and SiGe may be used therefor.

In the present disclosure, the term “perpendicular” includes not only strict perpendicularity but also, for example, variations and the like in perpendicularity in the manufacturing process provided that the variations are substantially perpendicular.

The embodiment of the present disclosure is described hereinbefore with reference to the specific examples. However, the embodiment of the present disclosure is not limited to those specific examples. For example, when the specific configuration of each elements such as the first to the third semiconductor layers, the first to the third electrodes, and the interlayer insulating film is reduced into practice by those skilled in the related art appropriately selecting the elements from a range of replacements in the related art, the embodiment is also included in the range of the present disclosure provided that the same effect as that of the present disclosure may be achieved.

In addition, combinations of any two or more elements of each specific example realized to the technically possible extent are also included in the range of the present disclosure provided that those combinations do not depart from the gist of the present disclosure.

Besides, all the semiconductor devices that may be embodied by those skilled in the related art appropriately modifying the design for the semiconductor device described as the embodiment of the present disclosure above also fall within the range of the present disclosure.

Besides, those skilled in the related art may perceive various modification examples and correction examples in the range of the idea of the present disclosure. Those modification examples and correction examples are also understood to fall within the range of the present disclosure.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first semiconductor layer comprising a nitride semiconductor;
a second semiconductor layer located over the first semiconductor layer comprising a nitride semiconductor, the second semiconductor layer having a different composition than the composition of the first semiconductor layer;
a first electrode located over the second semiconductor layer; and
a first insulating film comprising silicon nitride located over the second semiconductor layer, and covering at least a portion of the first electrode, the first insulating film having a hydrogen concentration greater than or equal to 5.0×10²¹ atoms/cm³ and less than or equal to 9.0×10²¹ atoms/cm³.

2. The device according to claim 1, wherein
the first semiconductor layer comprises Alₓ₁Ga₁₋ₓ₁N (where 0<x1<1), and
the second semiconductor layer comprises Alₓ₂Ga₁₋ₓ₂N (where x1<x2<1).

3. The device according to claim 1, wherein the second semiconductor layer forms a heterojunction with the first semiconductor layer.

4. The device according to claim 1, further comprising:
a second electrode located over the second semiconductor layer and spaced from the first electrode and electrically connected to the second semiconductor layer; and
a third electrode located over the second semiconductor layer and spaced from the first electrode and the second electrode and electrically connected to the second semiconductor layer.

5. The device according to claim 4, wherein the first insulating film is provided between the first electrode and the second electrode, and between the first electrode and the third electrode.

6. The device according to claim 5, wherein the thickness of the first insulating film is greater than or equal to 100 nanometers and less than or equal to 300 nanometers.

7. The device according to claim 5, wherein the width of the second electrode is greater than or equal to 3 μm and less than or equal to 8 μm.

8. The device according to claim 5, wherein the distance between the first electrode and the second electrode is greater than or equal to 1 μm and less than or equal to 3 μm.

9. The device according to claim 5, wherein the distance between the first electrode and the third electrode is greater than or equal to 5 μm and less than or equal to 20 μm.

10. A method of forming a compound semiconductor device comprising a first semiconductor layer and a second semiconductor layer having different lattice constants, comprising;
forming a first electrode having a first side and a second side over the second semiconductor layer; and
forming an insulating layer adjacent to, and extending from, the first and second sides of the first electrode and over the second semiconductor layer; wherein
the hydrogen concentration of the insulating layer is greater than or equal to 5.0×10²¹ atoms/cm³ and less than or equal to 9.0×10²¹ atoms/cm³.

11. The method of claim 10, wherein the insulating layer is formed by plasma chemical vapor deposition.

12. The method of claim 11, wherein the insulating layer is formed using a SiH₄ gas, an NH₃ gas, and an N₂ gas.

13. The method of claim 10, wherein the insulating layer and the first electrode are formed over a second insulating film formed directly on the second semiconductor layer.

14. The method of claim 10, wherein the thickness of the insulating film is greater than or equal to 100 nanometers and less than or equal to 300 nanometers.

15. A semiconductor device comprising a first semiconductor layer and a second semiconductor layer in contact with one another and having different lattice constants, wherein the variation of the ON resistance throughout the device is less than 5 percent.

16. The semiconductor device of claim 15, further comprising:
a first electrode disposed over the second semiconductor layer; and
an insulating layer adjacent to, and extending from the first electrode and over the second semiconductor layer; wherein
the hydrogen concentration of the insulating layer is greater than or equal to 5.0×10²¹ atoms/cm³ and less than or equal to 9.0×10²¹ atoms/cm³.

17. The semiconductor device of claim 16, wherein a thickness of the insulating film is greater than or equal to 100 nanometers and less than or equal to 300 nanometers.

18. The semiconductor device of claim 16, further comprising:
a second electrode spaced from the first electrode and contacting the second semiconductor layer, wherein
the distance between the first electrode and the second electrode is greater than or equal to 1 μm and less than or equal to 3 μm.

19. The device according to claim 16, further comprising:
a third electrode spaced from the first electrode and contacting the second semiconductor layer, wherein
the distance between the first electrode and the third electrode is greater than or equal to 5 μm and less than or equal to 20 μm.

20. The semiconductor device of claim 16, wherein the device is an HEMT.
